(19) United States
(12) Patent Application Publication
(10) Pub. No.: US 2011/0180138 A1
(43) Pub. Date: Jul. 28, 2011

(54) PASTE COMPOSITION FOR ELECTRODE AND PHOTOVOLTAIC CELL

(75) Inventors: Shuuichirou Adachi, Tsukuba-shi (JP); Masato Yoshida, Tsukuba-shi (JP); Takeshi Nojiri, Tsukuba-shi (JP); Mitsunori Iwamuro, Tsukuba-shi (JP); Keiko Kizawa, Tsukuba-shi (JP); Takuya Aoyagi, Hitachi-shi (JP); Hiroki Yamamoto, Hitachi-shi (JP); Takashi Naito, Hitachi-shi (JP); Takahiko Kato, Hitachi-shi (JP)

(73) Assignee: HITACHI CHEMICAL COMPANY, LTD.

(21) Appl. No.: 13/012,947

(22) Filed: Jan. 25, 2011

Related U.S. Application Data
(60) Provisional application No. 61/298,129, filed on Jan. 25, 2010.

(51) Int. Cl. H01L 31/0224; H01L 31/0216; H01B 1/22

(52) U.S. Cl. 136/256; 252/512; 252/514

(57) ABSTRACT

The paste composition for an electrode includes metal particles having copper as a main component, glass particles including diphosphorus pentoxide and divanadium pentoxide and having a content of divanadium pentoxide of 1% by mass or more, a solvent, and a resin. Further, the photovoltaic cell has an electrode formed by using the paste composition for an electrode.

### CROSS-REFERENCE TO RELATED APPLICATIONS

This application claims priority under 35 U.S.C. 119(e) to Provisional U.S. Patent Application No. 61/298,129, filed Jan. 25, 2010, the disclosure of which is incorporated by reference herein.

### BACKGROUND OF THE INVENTION

1. Field of the Invention

The present invention relates to a paste composition for an electrode and a photovoltaic cell.

2. Description of the Related Art

Generally, a photovoltaic cell is provided with a surface electrode, in which the wiring resistance or contact resistance of the surface electrode is associated with a voltage loss involved in conversion efficiency, and further, the wiring width or shape has an influence on the amount of the incident sunlight (see, for example, “Sunlight Power Generation, Newest Technology and Systems”, edited by Yoshihiro Hamakawa, CMC Books, 2001, p. 26-27).

The surface electrode of the photovoltaic cell is usually formed in the following manner. That is, a conductive composition is applied onto an n-type semiconductor layer formed by thermally diffusing phosphorous and the like on the light-receiving surface side of a p-type silicon substrate at a high temperature by screen printing or the like, and sintered at a high temperature of from 800 to 900° C., thereby forming a surface electrode. This conductive composition for forming the surface electrode includes conductive metal powders, glass particles, various additives, and the like.

As the conductive metal powders, silver powders are generally used, but the use of metal powders other than silver powders is being investigated for various reasons. For example, a conductive composition capable of forming an electrode for a photovoltaic cell, including silver and aluminum, is disclosed (see, for example, Japanese Patent Application Laid-Open (JP-A) No. 2006-313744). In addition, a composition for forming an electrode, including metal nanoparticles including silver and metal particles other than silver, is disclosed (see, for example, JP-A No. 2008-226816).

### SUMMARY OF THE INVENTION

Silver that is generally used to form an electrode is a noble metal, and in view of the problems regarding resources and also from the viewpoint that the ore is expensive, it is desired to propose a paste material which replaces the silver-containing conductive composition (silver-containing paste). Examples of promising materials for replacing silver include copper which is employed in semiconductor wiring materials. Copper is abundant as a resource and the cost of the ore is inexpensive, at as low as about one hundredth of that of silver. However, copper is a material susceptible to oxidation at high temperatures of 200° C. or higher, and for example, in the composition for forming an electrode described in JP-A No. 2008-226816, when the composition includes copper as a conductive metal, a specific step in which the composition is sintered under an atmosphere of nitrogen or the like in order to form an electrode, is required.

It is an object of the present invention to provide a paste composition for an electrode, which is capable of forming an electrode having a low resistivity with inhibition of oxidation of copper at a time of sintering, and a photovoltaic cell having an electrode formed by using the paste composition for an electrode.

A first embodiment of the present invention is a paste composition for an electrode, including metal particles having copper as a main component, glass particles including diphosphorus pentoxide and divanadium pentoxide and having a content of divanadium pentoxide of 1% by mass or more, a solvent, and a resin. The glass particles preferably have a glass softening point of 600° C. or lower and a crystallization starting temperature of higher than 600° C.

Further, the paste composition for an electrode preferably further includes silver particles.

A second embodiment of the present invention is a photovoltaic cell having an electrode formed by sintering the paste composition for an electrode provided to a silicon substrate at a high temperature.

According to the present invention, a paste composition for an electrode, which is capable of forming an electrode having a low resistivity with inhibition of the oxidation of copper at a time of sintering, and a photovoltaic cell having an electrode formed by using the paste composition for an electrode can be provided.

### BRIEF DESCRIPTION OF THE DRAWINGS

FIG. 1 is a cross-sectional view of the photovoltaic cell according to the present invention.

FIG. 2 is a plane view showing the light-receiving surface side of the photovoltaic cell according to the present invention.

FIG. 3 is a plane view showing the back surface side of the photovoltaic cell according to the present invention.

FIG. 4A is a perspective view showing the AA cross-sectional constitution of the cell back contact-type photovoltaic cell according to the present invention.

FIG. 4B is a plane view showing the back surface side electrode structure of the cell back contact-type photovoltaic cell according to the present invention.

### DETAILED DESCRIPTION OF THE INVENTION

In the present specification, “to” denotes a range including each of the minimum value and the maximum value of the values described before and after the reference.

<Paste Composition for Electrode>

The paste composition for an electrode according to the present invention includes at least one kind of metal particle having copper as a main component, t least one kind of glass particles including diphosphorus pentoxide and divanadium pentoxide and having a content of divanadium pentoxide of 1% by mass or more, at least one kind of solvent, and at least one kind of resin.

By adopting such a constitution, it becomes possible to form an electrode having a low resistivity with inhibition of the oxidation of copper at a time of sintering.

(Metal Particles)

In the present invention, the metal particles having copper as a main component (hereinafter referred to as the “copper-containing particles” in some cases) mean the metal particles in which the content of the copper components in one metal particle is 50% by mass or more based on the total mass of the metal particles.

The metal particles having copper as a main component may be metal particles substantially consisting of copper, also including other atoms in an amount which dose not impair the effect of the invention, or may be metal particles including copper and components for imparting copper with oxidation resistance.

Examples of other atoms in the metal particles substantially consisting of copper include Sb, Si, K, Na, Li, Ba, Sr, Ca, Mg, Be, Zn, Pb, Cd, Tl, V, Sn, Al, Zr, W, Mo, Ti, Co, Ni, and Au. Among these, from the viewpoint of adjustment of the characteristics such as the oxidation resistance and a melting point, Al is preferably included.

Further, the content of other atoms contained in the copper-containing particles can be, for example, 3% by mass or less in the copper-containing particles, and from the viewpoint of the oxidation resistance and the low resistivity, it is preferably 1% by mass or less.

The metal particle including copper and components for imparting copper with oxidation resistance preferably has a peak temperature of an exothermic peak showing a maximum area in the simultaneous ThermoGravimetry/Differential Thermal Analysis (TG-DTA) of 280° C. or higher, more preferably from 280 to 800° C., and even more preferably from 350 to 750° C.

By using the metal particles having copper as a main component imparted with oxidation resistance, the oxidation of the metal copper can be inhibited at a time of sintering, thereby forming an electrode having a low resistivity. Further, the simultaneous ThermoGravimetry/Differential Thermal Analysis is typically carried out in air using a ThermoGravimetry/Differential Thermal Analysis analyzer (TG/DTA-6200 type, manufactured by SII Nano Technology Inc.), for example, under the conditions of a measurement temperature range: room temperature to 1000° C., a temperature rising rate: 40° C./min., and an atmospheric air flow rate: 200 ml/min.

Specific examples of the metal particles having copper as a main component, having a peak temperature in the exothermic peak showing a maximum area of 280° C. or higher in the simultaneous ThermoGravimetry/Differential Thermal Analysis (TG-DTA), include phosphorous-containing copper alloy particles, silver-coated copper particles, and copper particles surface-treated with at least one selected from the group consisting of triazole compounds, saturated fatty acids, unsaturated fatty acids, inorganic metal compound salts, organic metal compound salts, polyaniline-based resins, and metal alkoxides, and at least one selected therefrom is preferably used. Further, the copper-containing particles may be used singly or in combination of two or more kinds thereof.

The particle diameter of the copper-containing particle is not particularly limited, and it is preferably from 0.4 to 10 μm, and more preferably from 1 to 7 μm in terms of a particle diameter when the cumulative weight is 50% (hereinafter abbreviated as “D50%” in some cases). By setting the particle diameter to 0.4 μm or more, the oxidation resistance is improved more effectively. Further, by setting the particle diameter to 10 μm or less, the contact area at which the copper-containing particles contact each other in the electrode increases, whereby the resistivity is reduced more effectively. In addition, the particle diameter of the copper particle is measured by means of a MICROTRAC particle size distribution analyzer (MT3300 type, manufactured by Nikkiso Co., Ltd.).

In addition, the shape of the copper-containing particle is not particularly limited, and it may be any one of an approximately spherical shape, a flat shape, a block shape, a plate shape, a scale-like shape, and the like, but from the viewpoint of the oxidation resistance and the low resistivity, it is preferably an approximately spherical shape, a flat shape, or a plate shape.

The content of the copper-containing particles, and when including silver particles as described later, the total content of the copper particles and the surface-treated silver particles, which are respectively included in the paste composition for an electrode according to the present invention, can be, for example, from 70 to 94% by mass, and from the viewpoint of the oxidation resistance and the low resistivity, it is preferably from 72 to 90% by mass, and more preferably from 74 to 88% by mass.

Further, in the present invention, conductive particles other than the copper-containing particles may be used in combination therewith.

—Phosphorous-Containing Copper Alloy Particles—

As the phosphorous-containing copper alloy, a brazing material called copper phosphorus brazing (phosphorous concentration: approximately 7% by mass or less) is known. The copper phosphorus brazing is used as a copper to copper bonding agent, but by using the phosphorous-containing copper alloy particles as the copper-containing particles included in the paste composition for an electrode according to the present invention, the oxidation resistance is excellent and an electrode having a low resistivity can be formed. Furthermore, it becomes possible to sinter the electrode at a low temperature, and as a result, an effect of reducing a process cost can be obtained.

In the present invention, the content of phosphorous included in the phosphorous-containing copper alloy is preferably a content such that in the simultaneous ThermoGravimetry/Differential Thermal Analysis, the peak temperature of the exothermic peak showing a maximum area becomes 280° C. or higher. Specifically, the content of phosphorous is 0.01% by mass or more. In the present invention, from the viewpoint of the oxidation resistance and the low resistivity, it is preferably from 0.01% by mass to 8% by mass, more preferably from 0.5% by mass to 7.8% by mass, and even more preferably from 1% by mass to 7.5% by mass.

By setting the content of phosphorous included in the phosphorous-containing copper alloy to 8% by mass or less, a lower resistivity can be attained, and also, the productivity of the phosphorous-containing copper alloy is excellent. Further, by setting the content of phosphorous included in the phosphorous-containing copper alloy to 0.01% by mass or more, more excellent oxidation resistance can be attained.

Although the phosphorous-containing copper alloy particle is an alloy including copper and phosphorous, it may have other atoms. Examples of other atoms include Sb, Si, K, Na, Li, Ba, Sr, Ca, Mg, Be, Zn, Pb, Cd, Tl, V, Sn, Al, Zr, W, Mo, Ti, Co, Ni, and Au. Among these, from the viewpoint of adjustment of the characteristics such as the oxidation resistance and a melting point, Al is preferably included.

Further, the content of other atoms contained in the phosphorous-containing copper alloy particles can be, for example, 3% by mass or less in the phosphorous-containing copper alloy particles, and from the viewpoint of the oxidation resistance and the low resistivity, it is preferably 1% by mass or less.

The particle diameter of the phosphorous-containing copper alloy particle is not particularly limited, and it is preferably from 0.4 to 10 μm, and more preferably from 1 to 7 μm in terms of a particle diameter when the cumulative weight is 50% (hereinafter abbreviated as “D50%” in some cases). By setting the particle diameter to 0.4 μm or more, the oxidation resistance is improved more effectively. Further, by setting the particle diameter to 10 μm or less, the contact area at which the copper-containing particles contact each other in the electrode increases, whereby the resistivity is reduced more effectively.

In addition, the shape of the phosphorous-containing copper alloy particle is not particularly limited, and it may be any one of an approximately spherical shape, a flat shape, a block shape, a plate shape, a scale-like shape, and the like, but from the viewpoint of the oxidation resistance and the low resistivity, it is preferably an approximately spherical shape, a flat shape, or a plate shape.

The phosphorous copper alloy can be prepared by a typically used method. Further, the phosphorous-containing copper alloy particle can be prepared by a general method for preparing metal powders using a phosphorous-containing copper alloy that is prepared so as to give a desired phosphorous content, and it can be prepared by, for example, a general method using a water atomization method. The water atomization method is described in the Handbook of Metal (Maruzen CO., LTD. Publishing Dept.) or the like.

Specifically, for example, a desired phosphorous-containing copper alloy particle can be prepared by dissolving a phosphorous-containing copper alloy, forming a powder by nozzle spray, drying the obtained powders, and classifying them. Further, a phosphorous-containing copper alloy particle having a desired particle diameter can be prepared by appropriately selecting the classification condition.

The content of the phosphorous-containing copper alloy particles included in the paste composition for an electrode according to the present invention, can be, for example, from 70 to 94% by mass, and from the viewpoint of the oxidation resistance and the low resistivity, it is preferably from 72 to 90% by mass, and more preferably from 74 to 88% by mass.

Furthermore, in the present invention, the phosphorous-containing copper alloy particles may be used singly or in combination of two or more kinds thereof. In addition, they may be used in combination with the copper-containing particles, having a peak temperature in the exothermic peak showing a maximum area of 280° C. or higher, other than the phosphorous copper alloy particles.

Moreover, in the present invention, from the viewpoint of the oxidation resistance and the low resistivity of the electrode, it is preferable that the phosphorous-containing copper alloy particles having a phosphorous content of from 0.01 to 8% by mass be contained in an amount of from 70 to 94% by mass based on the paste composition for an electrode, and it is more preferable that the phosphorous-containing copper alloy particles having a phosphorous content of 1 to 7.5% by mass be contained in an amount of from 74 to 88% by mass based on the paste composition for an electrode.

Further, in the present invention, conductive particles other than the phosphorous-containing copper alloy particles may be used in combination therewith.

—Silver-Coated Copper Particles—

As the silver-coated copper particle in the present invention, any one in which at least a part of the copper particle surface is coated with silver is suitable. By using the silver-coated copper particles as the copper-containing particles included in the paste composition for an electrode according to the present invention, the oxidation resistance is excellent and an electrode having a low resistivity can be formed. Further, by coating the copper particle with silver, the interfacial resistance between the silver-coated copper particles and the silver particle is reduced, and thus, an electrode having a further reduced resistivity can be formed. In addition, when moisture is incorporated during the formation of a paste composition, an effect that the oxidation of copper at room temperature can be inhibited by using the silver-coated copper particles and the pot life can be enhanced can be obtained.

The coating amount of silver (silver content) in the silver-coated copper particles is preferably a coating amount (silver content) such that in the simultaneous ThermoGravimetry/Differential Thermal Analysis, the peak temperature of the exothermic peak showing a maximum area is 280° C. or higher. Specifically, the coating amount of silver is 1% by mass or more based on the total mass of the silver-coated copper particles, but from the viewpoint of the oxidation resistance and the low resistivity of the electrode, it is preferably from 1% by mass to 88% by mass, more preferably from 3 to 80% by mass, and even more preferably from 5 to 75% by mass, based on the total mass of the silver-coated copper particles.

Furthermore, the particle diameter of the silver-coated copper particle is not particularly limited, and it is preferably from 0.4 to 10 μm, and more preferably from 1 to 7 μm in terms of a particle diameter when the cumulative weight is 50% (hereinafter abbreviated as “D50%” in some cases). By setting the particle diameter to 0.4 μm or more, the oxidation resistance is improved more effectively. Further, by setting the particle diameter to 10 μm or less, the contact area at which the copper-containing particles contact each other in the electrode increases, whereby the resistivity is reduced more effectively.

In addition, the shape of the silver-coated copper particle is not particularly limited, and it may be any one of an approximately spherical shape, a flat shape, a block shape, a plate shape, a scale-like shape, and the like, but from the viewpoint of oxidation resistance and low resistivity, it is preferably an approximately spherical shape, a flat shape, or a plate shape.

Copper constituting the silver-coated copper particle may contain other atoms. Examples of other atoms include Sb, Si, K, Na, Li, Ba, Sr, Ca, Mg, Be, Zn, Pb, Cd, Tl, V, Sn, Al, Zr, W, Mo, Ti, Co, Ni, and Au. Among these, from the viewpoint of adjustment of the characteristics such as the oxidation resistance and a melting point, Al is preferably included.

Further, the content of other atoms contained in the silver-coated copper particle can be, for example, 3% by mass or less in the silver-coated copper particle, and from the viewpoint of the oxidation resistance and the low resistivity, it is preferably 1% by mass or less.

Furthermore, it is also preferable that the silver-coated copper particle be one obtained by coating the above-described phosphorous-containing copper alloy with silver. Consequently, the oxidation resistance is further improved, and thus, the resistivity of the electrode to be formed is further reduced.

The details of the phosphorous-containing alloy in the silver-coated copper particles and preferred embodiments thereof are the same as for the above-described phosphorous-containing alloy.

The method for preparing the silver-coated copper particles is not particularly limited as long as it is a preparation method in which at least a part of the surface of the copper particles (preferably phosphorous-containing copper alloy particles) can be coated with silver. For example, copper powders (or phosphorous-containing copper alloy powders) are dispersed in an acidic solution such as sulfuric acid, hydrochloric acid, and phosphoric acid, and a chelator is added to the copper powder dispersion, thereby preparing a copper powder slurry. By adding a silver ion solution to the obtained copper powder slurry, a silver layer can be formed on the copper powder surface by a substitution reaction.

The chelator is not particularly limited, and, for example, ethylene diamine tetraacetate, triethylene diamine, diethylene triamine pentaacetate, imino diacetate, or the like can be used. Further, as the silver ion solution, for example, a silver nitrate solution, or the like can be used.

The content of the silver-coated copper particles, and when including silver particles as described later, the total content of the silver-coated copper particles and the silver particles, which are respectively included in the paste composition for an electrode according to the present invention, can be, for example, from 70 to 94% by mass, and from the viewpoint of the oxidation resistance and the low resistivity, it is preferably from 72 to 90% by mass, and more preferably from 74 to 88% by mass.

Furthermore, in the present invention, the silver-coated copper particles may be used singly or in combination of two or more kinds thereof. In addition, they may be used in combination with the copper-containing particles, having a peak temperature in the exothermic peak showing a maximum area of 280° C. or higher, other than the silver-coated copper particles.

In the present invention, from the viewpoint of the oxidation resistance and the low resistivity of the electrode, it is preferable that the silver-coated copper particles having a silver content of from 1 to 88% by mass based on the total mass of the silver-coated copper particle be contained in an amount of from 70 to 94% by mass (the total content of the silver-coated copper particles and the silver particles when including the silver particles as described later) based on the paste composition for an electrode, and it is more preferable that the silver-coated copper particles having a silver content of from 5 to 75% by mass be contained in an amount of from 74 to 88% by mass (the total content of the silver-coated copper particles and the silver particles when including the silver particles as described later) based on the paste composition for an electrode.

Furthermore, it is preferable that the silver-coated phosphorous-containing copper alloy particles having a silver content of from 1 to 88% by mass and a phosphorous content from 0.01 to 8% by mass be contained in an amount of from 70 to 94% by mass (the total content of the silver-coated phosphorous-containing copper alloy particles and the silver particles when including the silver particles as described later) based on the paste composition for an electrode, and it is more preferable that the silver-coated phosphorous-containing copper alloy particles having a silver content of from 5 to 75% by mass and a phosphorous content from 1 to 7.5% by mass be contained in an amount of from 74 to 88% by mass (the total content of the silver-coated phosphorous-containing copper alloy particles and the silver particles when including the silver particles as described later) based on the paste composition for an electrode.

Further, in the present invention, conductive particles other than the silver-coated copper particles may be used in combination therewith.

—Surface-Treated Copper Particles—

The copper-containing particles in the present invention are also preferably copper particles that have been surface-treated with at least one selected from a group consisting of a triazole compound, a saturated fatty acid, an unsaturated fatty acid, an inorganic metal compound salt, an organic metal compound salt, a polyaniline-based resin, and a metal alkoxide (hereinafter referred to as the “surface treatment agent”). By using the copper particles which have been surface-treated with at least one kind of surface treatment agent as the copper-containing particles included in the paste composition for an electrode according to the present invention, the oxidation resistance is excellent and an electrode having a low resistivity can be formed. In addition, when moisture is incorporated during the formation of a paste composition, an effect that oxidation of copper at room temperature can be inhibited by using the surface treatment agent and the pot life can be enhanced can be obtained.

Furthermore, in the present invention, the surface treatment agents may be used singly or in combination of two or more kinds thereof.

In the present invention, the surface-treated copper particles are surface-treated with at least one selected from the group consisting of a triazole compound, a saturated fatty acid, an unsaturated fatty acid, an inorganic metal compound salt, an organic metal compound salt, a polyaniline-based resin, and a metal alkoxide, but if necessary, other surface treatment agents may be used together therewith.

Examples of the triazole compound in the surface treatment agent include benzotriazole and triazole. Further, examples of the saturated fatty acid in the surface treatment agent include enanthic acid, caprylic acid, pelargonic acid, capric acid, undecylic acid, lauric acid, tridecyl acid, myristic acid, pentadecyl acid, stearic acid, nonadecanoic acid, arachic acid, and behenic acid. Further, examples of the unsaturated fatty acid in the surface treatment agent include acrylic acid, methacrylic acid, crotonic acid, isocrotonic acid, undecylenic acid, oleic acid, elaidic acid, cetoleic acid, brassidic acid, erucic acid, sorbic acid, linoleic acid, linolenic acid, and arachidonic acid.

Moreover, examples of the inorganic metal compound salt in the surface treatment agent include sodium silicate, sodium stannate, tin sulfate, zinc sulfate, sodium zincate, zirconium nitrate, sodium zirconate, zirconium oxide chloride, titanium sulfate, titanium chloride, and potassium oxalate titanate. Further, examples of the organic metal compound salt in the surface treatment agent include lead stearate, lead acetate, a p-cumylphenyl derivative of tetraalkoxyzirconium, and a p-cumylphenyl derivative of tetraalkoxytitanium. In addition, examples of the metal alkoxide in the surface treatment agent include titanium alkoxide, zirconium alkoxide, lead alkoxide, silicon alkoxide, tin alkoxide, and indium alkoxide.

Examples of other surface treatment agents include dodecyl benzene sulfonic acid. Further, when stearic acid or lead stearate is used as the surface treatment agent, at least one of stearic acid and lead stearate can be used in combination with lead acetate as the surface treatment agent to form an electrode having further improved oxidation resistance and thus having a lower resistivity.

As the surface-treated copper particle in the present invention, any one in which at least a part of the surface of the copper particles is coated with at least one kind of the surface treatment agents is suitable. The content of the surface treatment agent contained in the surface-treated copper particle is preferably a content such that the peak temperature of the exothermic peak showing a maximum area in the simultaneous ThermoGravimetry/Differential Thermal Analysis becomes 280° C. or higher. Specifically, the content is 0.01% by mass or more based on the total mass of the surface-treated copper particles, but from the viewpoint of the oxidation resistance and the low resistivity of the electrode, it is preferably from 0.01 to 10% by mass, and more preferably, from 0.1 to 8% by mass, based on the total mass of the surface-treated copper particles.

Copper constituting the surface-treated copper particles may contain other atoms. Examples of other atoms include Sb, Si, K, Na, Li, Ba, Sr, Ca, Mg, Be, Zn, Pb, Cd, Tl, V, Sn, Al, Zr, W, Mo, Ti, Co, Ni, and Au. Among these, from the viewpoint of adjustment of the characteristics such as the oxidation resistance and a melting point, Al is preferably included.

Further, the content of other atoms contained in the surface-treated copper particle can be, for example, 3% by mass or less in the surface-treated copper particle, and from the viewpoint of the oxidation resistance and the low resistivity, it is preferably 1% by mass or less.

Furthermore, it is also preferable that the surface-treated copper particles be those obtained by subjecting the above-described phosphorous-containing copper alloy to a surface treatment. Consequently, the oxidation resistance is further improved, and thus, the resistivity of the electrode to be formed is further reduced.

Details on the phosphorous-containing alloy in the surface-treated copper particles and preferred embodiments thereof are the same as for the above-described phosphorous-containing alloy.

Furthermore, the particle diameter of the surface-treated copper particle is not particularly limited, and it is preferably from 0.4 to 10 μm, and more preferably from 1 to 7 μm in terms of a particle diameter when the cumulative weight is 50% (hereinafter abbreviated as “D50%” in some cases). By setting the particle diameter to 0.4 μm or more, the oxidation resistance is improved more effectively. Further, by setting the particle diameter to 10 μm or less, the contact area at which the copper-containing particles contact each other in the electrode increases, whereby the resistivity is reduced more effectively.

In addition, the shape of the surface-treated copper particle is not particularly limited, and it may be any one of an approximately spherical shape, a flat shape, a block shape, a plate shape, a scale-like shape, and the like, but from the viewpoint of oxidation resistance and low resistivity, it is preferably an approximately spherical shape, a flat shape, or a plate shape.

The method for the surface treatment of the copper particles using a surface treatment agent can be appropriately selected according to the surface treatment agent to be used. For example, a surface treatment solution in which a surface treatment agent is dissolved in a solvent capable of dissolving the surface treatment agent is prepared, and copper particles are immersed therein and then dried, whereby at least a part of the surface of the copper particles can be coated with the surface treatment agent.

The solvent capable of dissolving the surface treatment agent can be appropriately selected depending on the surface treatment agent. Examples of the solvent include water, alcohol-based solvents such as methanol, ethanol, and isopropanol, glycol-based solvents such as ethylene glycol monoethyl ether, carbitol-based solvents such as diethylene glycol monobutyl ether, and carbitol acetate-based solvents such as diethylene glycol monoethyl ether acetate.

Specifically, for example, when benzotriazole, triazole, or dodecyl benzene sulfonic acid is used as the surface treatment agent, a surface treatment solution can be prepared using the alcohol-based solvent, thereby subjecting the copper particles to a surface treatment.

In addition, when stearic acid or lead stearate is used as the surface treatment agent, a surface treatment solution can be prepared using the alcohol-based solvent.

The concentration of the surface treatment agent in the surface treatment solution can be appropriately selected depending on the kind of the surface treatment agent used and a desired extent of the surface treatment. For example, the concentration can be from 1 to 90% by mass, and preferably from 2 to 85% by mass.

The content of the surface-treated copper particles, and when including silver particles as described later, the total content of the surface-treated copper particles and the silver particles, which are respectively included in the paste composition for an electrode according to the present invention, can be, for example, from 70 to 94% by mass, and from the viewpoint of the oxidation resistance and the low resistivity, it is preferably from 72 to 90% by mass, and more preferably from 74 to 88% by mass.

Furthermore, in the present invention, the surface-treated copper particles may be used singly or in combination of two or more kinds thereof. In addition, they may be used in combination with the copper-containing particles, having a peak temperature in the exothermic peak showing a maximum area of 280° C. or higher, other than the surface-treated copper particles.

In the present invention, from the viewpoint of the oxidation resistance and the low resistivity of the electrode, it is preferable that the copper particles, in which at least one selected from the group consisting of a triazole compound, a saturated fatty acid, an unsaturated fatty acid, an inorganic metal compound salt, an organic metal compound salt, a polyaniline-based resin, and a metal alkoxide is subjected to from 0.01 to 10% by mass surface treatment, be contained in an amount of from 70 to 94% by mass (the total content of the surface-treated copper particles and the silver particles when including the silver particles as described later) based on the paste composition for an electrode, and it is more preferable that the copper particles, in which at least one selected from the group consisting of a triazole compound, a saturated fatty acid, an unsaturated fatty acid, and an inorganic metal compound salt is subjected to from 0.1 to 8% by mass surface treatment, be contained in an amount of from 74 to 88% by mass (the total content of the surface-treated copper particles and the silver particles when including the silver particles as described later) based on the paste composition for an electrode.

Furthermore, it is preferable that the phosphorous-containing copper alloy particles, in which at least one selected from the group consisting of a triazole compound, a saturated fatty acid, an unsaturated fatty acid, an inorganic metal compound salt, an organic metal compound salt, a polyaniline-based resin, and a metal alkoxide is subjected to from 0.01 to 10% by mass surface treatment and the phosphorous content is 8% by mass or less, be contained in an amount of from 70 to 94% by mass (the total content of the surface-treated phosphorous-containing copper alloy particles and the silver particles when including the silver particles as described later) based on the paste composition for an electrode, and it is more preferable that the phosphorous-containing copper alloy particles, in which at least one selected from the group consisting of a triazole compound, a saturated fatty acid, an unsaturated fatty acid, and an inorganic metal compound salt is subjected to from 0.1 to 8% by mass surface treatment, and the phosphorous content is from 1 to 7.5% by mass, be contained in an amount of from 74 to 88% by mass (the total content of the surface-treated phosphorous-containing copper alloy particles and the silver particles when including the silver particles as described later) based on the paste composition for an electrode.

Further, in the present invention, conductive particles other than the surface-treated copper particles may be used in combination therewith.

(Glass Particles)

The paste composition for an electrode according to the present invention includes at least one kind of the glass particles including diphosphorus pentoxide and divanadium pentoxide and having a content of divanadium pentoxide of 1% by mass or more. By incorporating glass particles having such the specific composition in the paste composition for an electrode, the fire-through property is improved, and thus, an ohmic contact between the electrode and the silicon substrate is formed at a lower resistivity.

As mentioned herein, the fire-through indicates that at an electrode-forming temperature, the glass particle and the silicon nitride film which is an anti-reflection film are reacted with each other, and as a result, the silicon nitride film is removed and the ohmic contact between the electrode and the silicon substrate is formed.

The glass particles include glass containing diphosphorus pentoxide and divanadium pentoxide (P₂O₅—V₂O₅-based glass). By incorporating diphosphorus pentoxide and divanadium pentoxide, the oxidation resistance is further improved, the resistivity of the electrode to be formed is further reduced, and the fire-through property is improved. It is thought that this is caused by, for example, decrease in the softening point of glass as a result of further including divanadium pentoxide.

The content of divanadium pentoxide in the glass particles is 1% by mass or more based on the total mass of glass, but from the viewpoint of the oxidation resistance and the low resistivity of the electrode, it is more preferably from 1 to 70% by mass.

Further, the content of the diphosphorus pentoxide is not particularly limited, and from the viewpoint of the oxidation resistance and the low resistivity of the electrode, it is preferably 1% by mass or more, and more preferably from 4 to 50% by mass.

Moreover, the diphosphorus pentoxide-divanadium pentoxide-based glass (P₂O₅—V₂O₅-based glass) can further include other components, if necessary. Examples of other components include barium oxide (BaO), manganese dioxide (MnO₂), sodium oxide (Na₂O), potassium oxide (K₂O), zirconium dioxide (ZrO₂), tungsten trioxide (WO₃), tellurium oxide (TeO), molybdenum trioxide (MoO₃), and diantimony trioxide (Sb₂O₃). By further including other components, silicon dioxide derived from the silicon nitride can be more efficiently incorporated. Further, the softening or melting temperature can be further reduced. In addition, the reaction with the copper-containing particles or silver particles that are added, if necessary, can be inhibited.

The glass particles are preferably glass particles containing glass having a glass softening point of 600° C. or lower and a crystallization starting temperature of higher than 600° C., from the viewpoint of the oxidation resistance and the low resistivity of the electrode. Further, the glass softening point is measured by a general method using a ThermoMechanical Analyzer (TMA), and the crystallization starting temperature is measured by a general method using a ThermoGravimetry/Differential Thermal Analyzer (TG/DTA).

The paste composition for an electrode according to the present invention may further include at least one kind of other glass particles which do not contain diphosphorus pentoxide or divanadium pentoxide, in addition to the P₂O₅—V₂O₅-based glass.

Preferable examples of other glass particles include glass particles including lead-containing glass from the viewpoint of being capable of efficiently incorporating silicon dioxide. Examples of such lead-containing glass include those described in Japanese Patent 03050064 and the like, which can be suitably used in the present invention.

Furthermore, in the present invention, in consideration of an effect on the environment, it is preferable to use lead-free glass which does not substantially contain lead. Examples of the lead-free glass include lead-free glass described in Paragraphs 0024 to 0025 of JP-A No. 2006-313744, and lead-free glass described in JP-A No. 2009-188281 and the like, and it is also preferable to appropriately select one from the lead-free glass as above and apply it in the present invention.

The content of the glass particles is preferably from 0.1% by mass to 10% by mass, more preferably from 0.5 to 8% by mass, and even more preferably from 1 to 7% by mass, based on the total mass of the paste composition for an electrode. By incorporating glass particles at a content in this range, the oxidation resistance, the low resistivity of the electrode, and the low contact resistance can be attained more effectively.

In the present invention, it is preferable to include glass particles including P₂O₅—V₂O₅-based glass having a content of V₂O₅ of 1% by mass or more in an amount of from 0.1% by mass to 10% by mass, it is more preferable to include glass particles including P₂O₅—V₂O₅-based glass having a content of V₂O₅ of from 1 to 70% by mass in an amount of from 0.5 to 8% by mass, and it is even more preferable to include glass particles including P₂O₅—V₂O₅-based glass having a content of V₂O₅ of from 1 to 70% by mass in an amount of from 1 to 7% by mass.

(Solvent and Resin)

The paste composition for an electrode according to the present invention includes at least one kind of solvent and at least one kind of resin, thereby enabling adjustment of the liquid physical properties (for example, viscosity and surface tension) of the paste composition for an electrode according to the present invention due to application method, when selected the paste composition is provided to the silicon substrate.

The solvent is not particularly limited. Examples thereof include hydrocarbon-based solvents such as hexane, cyclohexane, and toluene; chlorinated hydrocarbon-based solvents such as dichloroethylene, dichloroethane, and dichlorobenzene; cyclic ether-based solvents such as tetrahydrofuran, furan, tetrahydropyran, pyran, dioxane, 1,3-dioxolane, and trioxane; amide-based solvents such as N,N-dimethylformamide and N,N-dimethylacetamide; sulfoxide-based solvents such as dimethylsulfoxide, diethylsulfoxide; ketone-based solvents such as acetone, methyl ethyl ketone, diethyl ketone, and cyclohexanone; alcohol-based compounds such as ethanol, 2-propanol, 1-butanol, and diacetone alcohol; polyhydric alcohol ester-based solvents such as 2,2,4-trimethyl-1,3-pentanediol monoacetate, 2,2,4-trimethyl-1,3-pentanediol monopropionate, 2,2,4-trimethyl-1,3-pentanediol monobutyrate, 2,2,4-trimethyl-1,3-pentanediol monoisobutyrate, 2,2,4-triethyl-1,3-pentanediol monoacetate, ethylene glycol monobutyl ether acetate, and diethylene glycol monobutyl ether acetate; polyhydric alcohol ether-based solvents such as butyl cellosolve and diethylene glycol diethyl ether; terpene-based solvents such as α-terpinene, α-terpineol, myrcene, alloocimene, limonene, dipentene, α-pinene, β-pinene, terpineol, carvone, ocimene, and phellandrene, and mixtures thereof.

As the solvent in the present invention, from the viewpoint of applicability and printability when forming the paste composition for an electrode on a silicon substrate, at least one selected from polyhydric alcohol ester-based solvents, terpene-based solvents, and polyhydric alcohol ether-based solvents is preferred, and at least one selected from polyhydric alcohol ester-based solvents and terpene-based solvents is more preferred.

In the present invention, the solvents may be used singly or in combination of two or more kinds thereof.

Furthermore, as the resin, a resin that is generally used in the art can be used without any limitation as long as it is a resin that is thermally decomposable by sintering. Specific examples thereof include cellulose-based resins such as methyl cellulose, ethyl cellulose, carboxymethyl cellulose, and nitrocellulose; polyvinyl alcohols; polyvinyl pyrrolidones; acryl resins; vinyl acetate-acrylic ester copolymers; butyral resins such as polyvinyl butyral; alkyd resins such as phenol-modified alkyd resins and castor oil fatty acid-modified alkyd resins; epoxy resins; phenol resins; and rosin ester resins.

As the resin in the present invention, from the viewpoint of the loss at a time of sintering, at least one selected from cellulose-based resins and acryl resins are preferred, and at least one selected from cellulose-based resins is more preferred.

In the present invention, the resins may be used singly or in combination of two or more kinds thereof.

In the paste composition for an electrode according to the present invention, the contents of the solvent and the resin can be appropriately selected in accordance with desired liquid physical properties, and the kinds of the solvent and the resin to be used. For example, the total content of the solvent and the resin is preferably from 3% by mass to 29.9% by mass, more preferably from 5% by mass to 25% by mass, and even more preferably from 7% by mass to 20% by mass, based on the total mass of the paste composition for an electrode.

By setting the total content of the solvent and the resin in the above-described ranges, the provision suitability becomes better when the paste composition for an electrode is provided to a silicon substrate, and thus, an electrode having a desired width and a desired height can be formed more easily.

(Silver Particles)

The paste composition for an electrode according to the present invention preferably further includes at least one kind of silver particle. By including the silver particle, the oxidation resistance is further improved, and the resistivity as the electrode is further reduced. In addition, an effect that the solder connectivity is improved when forming a photovoltaic cell module can be obtained. This can be considered to be as follows, for example.

Generally, in a temperature region from 600° C. to 900° C., which is an electrode-forming temperature region, a small amount of a solid solution of silver in copper, and a small amount of a solid solution of copper in silver are generated, and a layer of the copper-silver solid solution (solid solution region) is formed at an interface between copper and silver. When a mixture of the copper-containing particles and the silver particles is heated at a high temperature, and then slowly cooled to room temperature, it is thought that the solid solution region is not generated. However when forming an electrode, since cooling is carried out for a few seconds from a high temperature region to a room temperature when forming an electrode, it is thought that the layer of the solid solution at a high temperature covers the surface of the silver particles and the copper-containing particles as a non-equilibrium solid solution phase or as a eutectic structure of copper and silver. It is assumed that such a copper-silver solid solution layer contributes to the oxidation resistance of the copper-containing particle at an electrode-forming temperature.

Further, the copper-silver solid solution layer starts to form at a temperature of from 300° C. to 500° C. or higher. Accordingly, it is thought that by using the silver particles in combination with the copper-containing particles whose peak temperature of the exothermic peak having a maximum area is 280° C. or higher measured in the simultaneous ThermoGravimetry/Differential Thermal Analysis, whereby the oxidation resistance of the copper-containing particles can be improved more effectively, and the resistivity of the electrode to be formed is further reduced.

Silver constituting the silver particles may contain other atoms which are inevitably incorporated. Examples of other atoms which are inevitably incorporated include Sb, Si, K, Na, Li, Ba, Sr, Ca, Mg, Be, Zn, Pb, Cd, Tl, V, Sn, Al, Zr, W, Mo, Ti, Co, Ni, and Au.

The particle diameter of the silver particle in the present invention is not particularly limited, and it is preferably from 0.4 μm to 10 μm, and more preferably from 1 μm to 5 μm in terms of a particle diameter when the cumulative weight is 50% (D50%). By setting the particle diameter to 0.4 μm or more, the oxidation resistance is improved more effectively. Meanwhile, by setting the particle diameter to 10 μm or less, the contact area at which the metal particles such as silver particles and copper-containing particles contact each other in the electrode, increases, whereby resistivity is reduced more effectively.

In the paste composition for an electrode according to the present invention, the relationship between the particle diameter (D50%) of the copper-containing particle and the particle diameter (D50%) of the silver particle is not particularly limited, and it is preferable that the particle diameter (D50%) of one is smaller than the particle diameter (D50%) of the other, and it is more preferable that the ratio of the particle diameter of one of the copper-containing particle and the silver particle with respect to the particle diameter of the other of the copper-containing particle and the silver particle be from 1 to 10. Consequently, the resistivity of the electrode is reduced more effectively. It is thought that this is caused by, for example, an increase in the contact area between the metal particles such as the copper-containing particles and silver particles in the electrode.

Moreover, the content of the silver particles in the paste composition for an electrode according to the present invention is preferably from 8.4 to 85.5% by mass, and more preferably from 8.9 to 80.1% by mass, based on the paste composition for an electrode, from the viewpoint of the oxidation resistance and the low resistivity of the electrode.

Further, in the present invention, from the viewpoint of the oxidation resistance and the low resistivity of the electrode, the content of the copper-containing particles when the total amount of the copper-containing particles and the silver particles are taken as 100% by mass is preferably from 9% by mass to 88% by mass, and more preferably from 17% by mass to 77% by mass. By setting the content of the copper-containing particles to 9% by mass or more, for example, in a case in which the glass particles include divanadium pentoxide, a reaction between silver and vanadium is suppressed, which results in a reduction of the volume resistance of the electrode. Also, by setting the content of the copper-containing particles to 88% by mass or less, copper included in the copper-containing particles is further inhibited from being in contact with the silicon substrate, thereby further reducing the contact resistance of the electrode.

Moreover, in the paste composition for an electrode according to the present invention, from the viewpoint of the oxidation resistance, the low resistivity of the electrode, and the applicability on a silicon substrate, the total content of the copper-containing particles and the silver particles is preferably from 70 to 94% by mass, and more preferably from 74 to 88% by mass. By setting the total content of the copper-containing particles and the silver particles to 70% by mass or more, a viscosity that is suitable for providing the paste composition for an electrode can be easily attained. Also, by setting the total content of the copper-containing particles and the silver particles to 94% by mass or less, the occurrence of abrasion when providing the paste composition for an electrode can be inhibited more effectively.

Moreover, in the paste composition for an electrode according to the present invention, from the viewpoint of the oxidation resistance and the low resistivity of the electrode, it is preferable that the total content of the copper-containing particles and the silver particles be from 70 to 94% by mass, the content of the glass particles be from 0.1 to 10% by mass, and the total content of the solvent and the resin be from 3 to 29.9% by mass, it is more preferable that the total content of the copper-containing particles and the silver particles be from 72 to 90% by mass, the content of the glass particles be from 0.5 to 8% by mass, and the total content of the solvent and the resin be from 5 to 25% by mass, and it is even more preferable that the total content of the copper-containing particles and the silver particles be 74 to 88% by mass, the content of the glass particles be from 1 to 7% by mass, and the total content of the solvent and the resin be from 7 to 20% by mass.

(Flux)

The paste composition for an electrode includes at least one kind of flux. By including the flux, the oxidation resistance is further improved, and the resistivity of the electrode to be formed is further reduced. Also, an effect that adhesion between the electrode material and the silicon substrate is improved can be obtained.

The flux in the present invention is not particularly limited as long as it can remove the oxide film formed on the surface of the copper-containing particle. Specific preferable examples of the flux include fatty acids, boric acid compounds, fluoride compounds, and fluoroborate compounds.

More specific examples thereof include lauric acid, myristic acid, palmitic acid, stearic acid, sorbic acid, stearol acid, boron oxide, potassium borate, sodium borate, lithium borate, potassium fluoroborate, sodium fluoroborate, lithium fluoroborate, acidic potassium fluoride, acidic sodium fluoride, acidic lithium fluoride, potassium fluoride, sodium fluoride, and lithium fluoride.

Among those, from the viewpoint of heat resistance at a time of sintering the electrode material (a property that the flux is not volatilized at a low sintering temperature) and complementing the oxidation resistance of the copper-containing particles, particularly preferable examples of the flux include potassium borate and potassium fluoroborate.

In the present invention, these fluxes can be respectively used singly or in combination of two or more kinds thereof.

Furthermore, the content of the flux in the paste composition for an electrode according to the present invention is preferably from 0.1 to 5% by mass, more preferably from 0.3 to 4% by mass, even more preferably from 0.5 to 3.5% by mass, particularly preferably from 0.7 to 3% by mass, and extremely preferably from 1 to 2.5% by mass, based on the total mass of the paste composition for an electrode, from the viewpoint of effectively exhibiting the oxidation resistance of the copper-containing particles and from the viewpoint of reducing the porosity of a portion from which the flux is removed at a time of completion of the sintering of the electrode material.

(Other Components)

Furthermore, the paste composition for an electrode according to the present invention can include, in addition to the above-described components, other components generally used in the art, if necessary. Examples of other components include a plasticizer, a dispersant, a surfactant, an inorganic binder, a metal oxide, a ceramic, and an organic metal compound.

The method for preparing the paste composition for an electrode according to the present invention is not particularly limited. The paste composition for an electrode according to the present invention can be prepared by dispersing and mixing copper-containing particles, glass particles, a solvent, a resin, silver particles to be added, if necessary, and the like, using a method that is typically used for dispersing and mixing.

<Method for Preparing Electrode Using Paste Composition for Electrode>

As for the method for preparing an electrode using the paste composition for an electrode according to the present invention, the paste composition for an electrode can be provided in a region in which the electrode is formed, dried, and then sintered to form the electrode in a desired region. By using the paste composition for an electrode, an electrode having a low resistivity can be formed even with a sintering treatment in the presence of oxygen (for example, in the atmosphere).

Specifically, for example, when an electrode for a photovoltaic cell is formed using the paste composition for an electrode, the paste composition for an electrode can be provided to a silicon substrate to a desired shape, dried, and then sintered to form an electrode for a photovoltaic cell having a low resistivity in a desired shape. Further, by using the paste composition for an electrode, an electrode having a low resistivity can be formed even with a sintering treatment in the presence of oxygen (for example, in the atmosphere).

Examples of the method for providing the paste composition for an electrode on a silicon substrate include screen printing, an ink-jet method, and a dispenser method, but from the viewpoint of the productivity, application by screen printing is preferred.

When the paste composition for an electrode according to the present invention is applied by screen printing, it is preferable that the viscosity be in the range from 80 to 1000 Pa·s. Further, the viscosity of the paste composition for an electrode is measured using a Brookfield HBT viscometer at 25° C.

The amount of the paste composition for an electrode to be provided can be appropriately selected according to the size of the electrode formed. For example, the amount of the paste composition for an electrode to be provided can be from 2 to 10 g/m², and preferably from 4 to 8 g/m².

Moreover, as a heat treatment condition (sintering condition) when forming an electrode using the paste composition for an electrode according to the present invention, heat treatment conditions generally used in the art can be applied.

Generally, the heat treatment temperature (sintering temperature) is from 800 to 900° C., but when using the paste composition for an electrode according to the present invention, a heat treatment condition at a lower temperature can be applied, and for example, an electrode having excellent characteristics can be formed at a heat treatment temperature of from 600 to 850° C.

In addition, the heat treatment time can be appropriately selected according to the heat treatment temperatures, and it may be, for example, from 1 second to 20 seconds.

<Photovoltaic Cell>

The photovoltaic cell according to the present invention has an electrode formed by sintering the paste composition for an electrode provided to the silicon substrate in the presence of oxygen. As a result, a photovoltaic cell having excellent characteristics can be obtained, and the productivity of the photovoltaic cell is excellent.

Hereinbelow, specific examples of the photovoltaic cell according to the present invention will be described with reference to the drawings, but the present invention is not limited thereto.

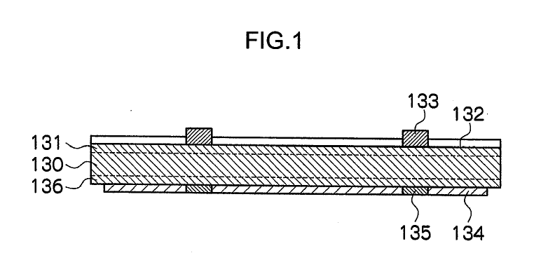

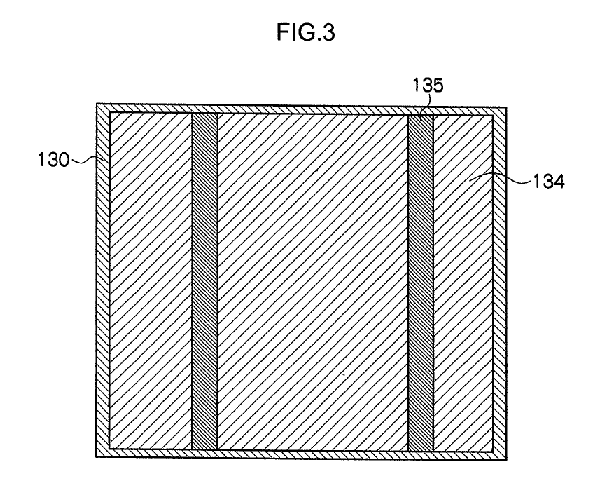

A cross-sectional view, and schematic views of the light-receiving surface and the back surface of one example of the representative photovoltaic cell elements are shown in FIGS. 1, 2, and 3, respectively.

Typically, monocrystalline or polycrystalline Si, or the like is used in a semiconductor substrate 130 of a photovoltaic cell element. This semiconductor substrate 130 contains boron and the like, and constitutes a p-type semiconductor. Unevenness (texture, not shown) is formed on the light-receiving surface side by etching so as to inhibit the reflection of sunlight. Phosphorous and the like are doped on the light-receiving surface side, a diffusion layer 131 of an n-type semiconductor with a thickness on the order of submicrons is provided, and a p/n junction is formed on the boundary with the p-type bulk portion. Also, on the light-receiving surface side, an anti-reflection layer 132 such as silicon nitride with a film thickness of around 100 nm is provided on the diffusion layer 131 by a vapor deposition method.

Next, a light-receiving surface electrode 133 provided on the light-receiving surface side, a current collection electrode 134 formed on the back surface, and an output extraction electrode 135 will be described. The light-receiving surface electrode 133 and the output extraction electrode 135 are formed from the paste composition for an electrode. Further, the current collection electrode 134 is formed from the aluminum electrode paste composition including glass powders. These electrodes are formed by applying the paste composition for a desired pattern by screen printing or the like, drying, and then sintering at about from 600 to 850° C. in an atmosphere.

In the present invention, by using the paste composition for an electrode, an electrode having an excellent resistivity and contact resistivity can be formed even with sintering at a relatively low temperature.

Here, on the light-receiving surface side, the glass particles included in the paste composition for an electrode forming the light-receiving surface electrode 133 undergo a reaction with the anti-reflection layer 132 (fire-through), thereby electrically connecting (ohmic contact) the light-receiving surface electrode 133 and the diffusion layer 131.

In the present invention, due to using the paste composition for an electrode to form the light-receiving surface electrode 133 including copper as a conductive metal, the oxidation of copper is inhibited, whereby the light-receiving surface electrode 133 having a low resistivity is formed with high productivity.

Further, on the back surface side, upon sintering, aluminum which is included in the aluminum electrode paste composition for forming the current collection electrode 134 is diffused on and into the back surface of the semiconductor substrate 130 to form an electrode component diffusion layer 136, and as a result, ohmic contact is formed among the semiconductor substrate 130, the current collection electrode 134, and the output extraction electrode 135.

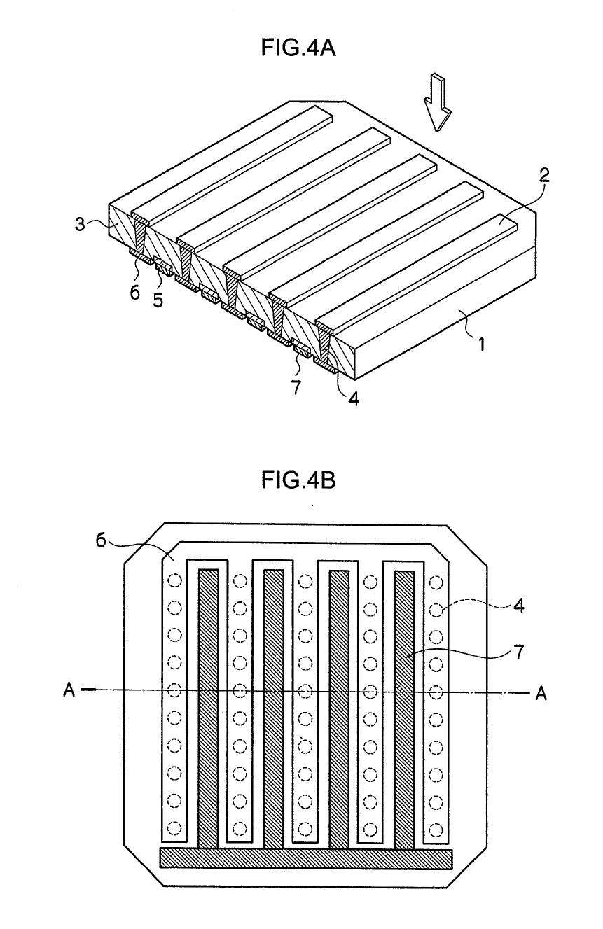

In FIG. 4 and FIG. 4B, the perspective view FIG. 4A of the light-receiving surface and the AA cross-section structure, and the plane view FIG. 4B of the back surface side electrode structure in one example of the photovoltaic cell element are shown as another embodiment according to the present invention.

As shown in FIG. 4A and FIG. 4B, in a cell wafer 1 including a silicon substrate of a p-type semiconductor, a through-hole passes through both sides of the light-receiving surface side and the back surface side is formed by laser drilling, etching, or the like. Further, a texture (not shown) for improving the efficiency of incident light is formed on the light-receiving surface side. Also, the light-receiving surface side has an n-type semiconductor layer 3 formed by n-type diffusion treatment, and an anti-reflection film (not shown) formed on the n-type semiconductor layer 3. These are prepared by the same process for a conventional crystal Si-type photovoltaic cell.

Next, the paste composition for an electrode according to the present invention is filled in the inside of the through-hole previously formed by a printing method or an ink-jet method, and also, the paste composition for an electrode according to the present invention is similarly printed in the grid shape on the light-receiving surface side, thereby forming a composition layer which forms the through-hole electrode 4 and the grid electrode 2 for current collection.

Here, regarding the paste used for filling and printing, although it is preferable to use the most suitable paste for each process from the point of view of properties such as viscosity, one paste of the same composition may be used for filling or printing at the same time.

On the other hand, a high-concentration doped layer 5 is formed on the opposite side of the light-receiving surface (back surface side) so as to prevent the carrier recombination. Here, as an impurity element forming the high-concentration doped layer 5, boron (B) or aluminum (Al) is used, and a p⁺ layer is formed. This high-concentration doped layer 5 may be formed by carrying out a thermal diffusion treatment using, for example, B as a diffusion source in the step of preparing a cell before forming the anti-reflection film, or when using Al, it may also be formed by printing an Al paste on the opposite surface side in the printing step.

Thereafter, the paste composition for an electrode is printed on the side of an anti-reflection film and is also filled in the inside of the through-hole, which is formed on the light-receiving surface side, and then is sintered at 650 to 850° C., whereby the paste composition can attain ohmic contact with the n-type layer as an under layer by a fire-through effect.

Furthermore, as shown in the plane view of FIG. 4B, the paste composition for an electrode according to the present invention is printed in stripe shapes on each of the n side and the p side, and sintered, and thus, the back surface electrodes 6 and 7 are formed on the opposite surface side.

In the present invention, the through-hole electrode 4, the grid electrode 2 for current collection, the back surface electrode 6, and the back surface electrode 7 are formed using the paste composition for an electrode, and thus, the through-hole electrode 4, the grid electrode 2 for current collection, the back surface electrode 6, and the back surface electrode 7, each of which includes copper as a conductive metal, inhibits the oxidation of copper, and has a low resistivity, are formed with high productivity.

Moreover, the paste composition for an electrode according to the present invention is not restricted to the applications of photovoltaic cell electrodes described above, and can also be appropriately used in applications such as, for example, electrode wirings and shield wirings of plasma displays, ceramic condensers, antenna circuits, various sensors circuits, and heat dissipation materials of semiconductor devices.

### EXAMPLES

Hereinbelow, the present invention will be described in detail with reference to Examples, but the present invention is not limited to these Examples. Further, unless otherwise specified, “parts” and “%” are based on mass.

### Example 1

(a) Preparation of Paste Composition for Electrode

Glass including 10 parts of vanadium oxide (V₂O₅), 29.6 parts of phosphorous oxide (P₂O₅), 10.4 parts of barium oxide (BaO), 10 parts of molybdenum oxide (MoO₃), 30 parts of tungsten oxide (WO₃), and 10 parts of potassium oxide (K₂O) (hereinafter abbreviated as “K41” in some cases) was prepared. The glass K41 obtained had a softening point of 554° C. and a crystallization temperature of higher than 600° C.

By using the glass K41 obtained, glass particles having a particle diameter (D50%) of 1.7 μm were obtained.

39.2 parts of the copper particles (purity 99.9%, particle diameter (D50%) 1.5 μm, manufactured by Mitsui Mining & Smelting Co., Ltd.), 45.9 parts of the silver particles (particle diameter (D50%) 3 μm, a high-purity chemical product manufactured by Sigma-Aldrich Corporation), 1.7 parts of glass particles (K41), and 13.2 parts of a butyl carbitol acetate (BCA) solution including 4% of ethyl cellulose (EC) were mixed and stirred in a mortar made of agate for 20 minutes under mixing, thereby preparing a paste composition 1 for an electrode.

(b) Preparation of Photovoltaic Cell

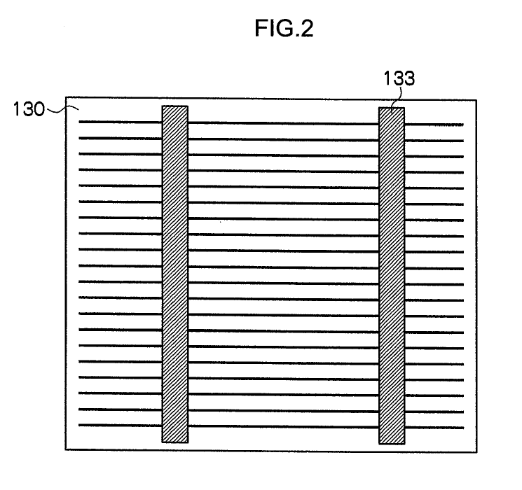

A p-type semiconductor substrate having a film thickness of 190 μm, in which an n-type semiconductor layer, a texture, and an anti-reflection film (silicon nitride film) were formed on the light-receiving surface, was prepared, and cut to a size of 125 mm×125 mm. The paste composition 1 for an electrode obtained above was printed on the light-receiving surface for an electrode pattern as shown in FIG. 2, using a screen printing method. The pattern of the electrode was constituted with finger lines with a 150 μm width and bus bars with a 1.1 mm width, and the printing conditions (a mesh of a screen plate, a printing speed, a printing pressure) were appropriately adjusted so as to give a film thickness after sintering of 20 μm. The resultant was put into an oven heated at 150° C. for 15 minutes, and the solvent was removed by evaporation.

Subsequently, an aluminum electrode paste was similarly printed on the entire surface of the back surface by screen printing. The printing conditions were appropriately adjusted so as to give a film thickness after sintering of 40 μm. The resultant was put into an oven heated at 150° C. for 15 minutes, and the solvent was removed by evaporation.

Then, a heating treatment (sintering) was carried out at 850° C. for 2 seconds under an air atmosphere in an infrared rapid heating furnace to prepare a cell 1 of a photovoltaic cell having a desired electrode formed therein.

### Examples 2 to 8

In the same manner as in Example 1, except that the particle diameter (D50%) and the content of the copper particles, the particle diameter (D50%) and the content of the silver particles, the type and the content of the glass particles, and the content of the butyl carbitol acetate (BCA) solution including 4% of ethyl cellulose (EC) were changed as shown in Table 1 in Example 1, paste compositions 2 to 8 for an electrode were prepared.

Further, the glass particles (AY1) included 45 parts of vanadium oxide (V₂O₅), 24.2 parts of phosphorous oxide (P₂O₅), 20.8 parts of barium oxide (BaO), 5 parts of antimony oxide (Sb₂O₃), and 5 parts of tungsten oxide (WO₃), and had a particle diameter (D50%) of 1.7 μm. Further, the glass had a softening point of 492° C. and a crystallization temperature of higher than 600° C.

In the same manner as in Example 1, except that the temperature for heating treatment and the treatment time were changed as shown in Table 1, using the paste compositions 2 to 8 for an electrode obtained, cells 2 to 8 of photovoltaic cells each having a desired electrode formed therein were prepared, respectively.

### Comparative Example 1

In the same manner as in Example 1, except that a commercially available paste (manufactured by E. I. du Pont de Nemours and Company, PV159) for a photovoltaic cell, including silver particles and lead glass particles, was used as the paste composition for an electrode in Example 1, a cell C1 of a photovoltaic cell was prepared.

### Comparative Example 2

In the same manner as in Example 1, except that the copper-containing particles were not used in the preparation of the paste composition for an electrode and the respective components were changed to the compositions shown in Table 1 in Example 1, a paste composition C2 for an electrode was prepared.

In the same manner as in Example 1, except that the paste composition C2 for an electrode not including copper-containing particles was used, a cell C2 of a photovoltaic cell was prepared.

TABLE 1

| | Copper- | | | | | | | |
|---|---|---|---|---|---|---|---|---|
| | containing | | | | | | | |
| | particles | | Silver particles | | | | 4% EC- | |
| | | Particle | | Particle | | | containing | Treatment |
| | | diameter | | diameter | Glass particles | | BCA | temperature/ |
| | Content | (D50%) | Content | (D50%) | Content | | solution | Treatment |
| Example | (parts) | (μm) | (parts) | (μm) | (parts) | Type | (parts) | time |
| Example 1 | 39.2 | 1.5 | 45.9 | 1 | 1.7 | K41 | 13.2 | 850° C./ |
| | | | | | | | | 2 seconds |
| Example 2 | 39.2 | 1.1 | 45.9 | 3 | 1.7 | K41 | 13.2 | 850° C./ |
| | | | | | | | | 2 seconds |
| Example 3 | 39.2 | 1.1 | 45.9 | 3 | 1.7 | AY1 | 13.2 | 850° C./ |
| | | | | | | | | 2 seconds |
| Example 4 | 39.2 | 1.5 | 45.9 | 3 | 1.7 | K41 | 13.2 | 850° C./ |
| | | | | | | | | 2 seconds |
| Example 5 | 38.4 | 1.5 | 45 | 3 | 3.4 | K41 | 13.2 | 850° C./ |
| | | | | | | | | 2 seconds |
| Example 6 | 40.6 | 1.5 | 47.5 | 1 | 1.8 | K41 | 10.1 | 850° C./ |
| | | | | | | | | 2 seconds |
| Example 7 | 34.9 | 1.5 | 50.2 | 1 | 1.7 | AY1 | 13.2 | 850° C./ |
| | | | | | | | | 2 seconds |
| Example 8 | 56.2 | 1.5 | 28.9 | 1 | 1.7 | K41 | 13.2 | 850° C./ |
| | | | | | | | | 2 seconds |
| Comparative | 0 | — | 85.1 | 3 | 1.7 | K41 | 13.2 | 850° C./ |
| Example 2 | | | | | | | | 2 seconds |

<Evaluation>

The cells of the photovoltaic cells prepared were evaluated with a combination of WXS-155 S-10 manufactured by Wacom Electric Co., Ltd. as artificial sunlight and a measurement device of I-V CURVE TRACER MP-160 (manufactured by EKO INSTRUMENT CO., LTD.) as a current-voltage (I-V) evaluation and measurement device. Eff (conversion efficiency), FF (fill factor), Voc (open voltage), and Jsc (short circuit current) indicating the power generation performances as a photovoltaic cell were obtained by carrying out the measurement in accordance with each of JIS-C-8912, JIS-C-8913, and JIS-C-8914. The respective measured values obtained are shown in Table 2 as converted to relative values when the value measured in Comparative Example 1 was taken as 100.0.

TABLE 2

| | Treatment | Power generation performance as solar cell | | | |
|---|---|---|---|---|---|
| | temperature/ | Eff (relative value) | FF (relative value) | Voc (relative value) | Jsc (relative value) |
| Example | Treatment time | Conversion efficiency | Fill factor | Open voltage | Short circuit current |
| Example 1 | 850° C./ | 99.1 | 95.7 | 96.9 | 103.1 |
| | 2 seconds | | | | |
| Example 2 | 850° C./ | 103.9 | 103.4 | 98.2 | 107.4 |
| | 2 seconds | | | | |
| Example 3 | 850° C./ | 102.9 | 102.9 | 97.9 | 106.6 |
| | 2 seconds | | | | |
| Example 4 | 850° C./ | 104.9 | 108.4 | 97.2 | 112.6 |
| | 2 seconds | | | | |
| Example 5 | 850° C./ | 101.9 | 101.4 | 97.2 | 105.3 |
| | 2 seconds | | | | |
| Example 6 | 850° C./ | 99.6 | 102.7 | 100.9 | 99.8 |
| | 2 seconds | | | | |
| Example 7 | 850° C./ | 100.1 | 98.7 | 103 | 100.4 |
| | 2 seconds | | | | |
| Example 8 | 850° C./ | 101.1 | 103.4 | 100.6 | 99.5 |
| | 2 seconds | | | | |
| Comparative | 850° C./ | 100 | 100 | 100 | 100 |
| Example 1 | 2 seconds | | | | |
| Comparative | 850° C./ | 100.9 | 99.5 | 98.9 | 103.1 |
| Example 2 | 2 seconds | | | | |

From the above description, it can be seen that by using the paste composition for an electrode according to the present invention, an electrode having a low resistivity could be formed and a photovoltaic cell exhibiting excellent characteristics can be constituted even when metal particles having copper as a main component are used as a conductive metal of an electrode.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The exemplary embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

All publications, patent applications, and technical standards mentioned in this specification are herein incorporated by reference to the same extent as if each individual publication, patent application, or technical standard was specifically and individually indicated to be incorporated by reference.

1. A paste composition for an electrode, comprising:
metal particles having copper as a main component;
glass particles including diphosphorus pentoxide and divanadium pentoxide, the glass particles having a content of divanadium pentoxide of 1% by mass or more;
a solvent; and
a resin.

2. The paste composition for an electrode according to claim 1, wherein the glass particles have a glass softening point of 600° C. or lower and a crystallization starting temperature of higher than 600° C.

3. The paste composition for an electrode according to claim 1, further comprising silver particles.

4. A photovoltaic cell having an electrode formed by sintering the paste composition for an electrode according to claim 1 which is provided to a silicon substrate.

5. The paste composition for an electrode according to claim 2, further comprising silver particles.

6. A photovoltaic cell having an electrode formed by sintering the paste composition for an electrode according to claim 2 which is provided to a silicon substrate.

7. A photovoltaic cell having an electrode formed by sintering the paste composition for an electrode according to claim 3 which is provided to a silicon substrate.

8. A photovoltaic cell having an electrode formed by sintering the paste composition for an electrode according to claim 5 which is provided to a silicon substrate.
